(19) United States
(12) Patent Application Publication
(10) Pub. No.: US 2018/0053661 A1
(43) Pub. Date: Feb. 22, 2018

(54) PLASMA ETCHING APPARATUS AND METHOD OF MANUFACTURING A SEMICONDUCTOR DEVICE USING THE SAME

(71) Applicant: SAMSUNG ELECTRONICS CO. LTD., Suwon-si (KR)

(72) Inventors: MIN-JOON PARK, SEONGNAM-SI (KR); TAE-HWA KIM, HWASEONG-SI (KR); JAE-HYUN LEE, YONGIN-SI (KR); SANG-DONG KWON, SEOUL (KR)

(21) Appl. No.: 15/443,378

(22) Filed: Feb. 27, 2017

(30) Foreign Application Priority Data
Aug. 17, 2016 (KR) 10-2016-0104203

(51) Int. Cl. H01L 21/3065; H01L 21/67; H01L 21/311; H01J 37/32

(52) U.S. Cl. CPC H01L 21/3065; H01L 21/67069; H01J 2237/334; H01J 37/321; H01J 37/32715; H01L 21/31116

(57) ABSTRACT

Disclosed are a plasma etching apparatus and a method of manufacturing semiconductor devices using the same. The plasma etching apparatus includes a process chamber. A source supplier is positioned at an upper portion of the process chamber. The source supplier is configured to supply source gases for an etching process. A substrate holder is positioned at a lower portion of the process chamber opposite to the source supplier. The substrate holder is configured to support a substrate. A first power source is configured to apply a high frequency power to capacitively couple the source gases into a capacitively coupled plasma (CCP) in the process chamber. A second power source is configured to apply a low frequency pulse power at a low duty ratio of less than or equal to about 0.5:1. The low frequency pulse power is configured to guide the CCP toward the substrate supported by the substrate holder.

### CROSS-REFERENCE TO RELATED APPLICATION

This application claims priority under 35 U.S.C §119 to Korean Patent Application No. 10-2016-0104203 filed on Aug. 17, 2016 in the Korean Intellectual Property Office, the disclosure of which is incorporated by reference herein in its entirety.

### 1. Technical Field

Exemplary embodiments of the present inventive concept relate to a plasma etching apparatus and a method of manufacturing a semiconductor device using the same.

### 2. Discussion of Related Art

Semiconductor devices may be high integration and high performance devices. An aspect ratio of fine patterns of semiconductor devices may be relatively high. The high aspect ratio of the pattern structure may result in various etch depth loadings such as a poor etching rate, an insufficient etching selectivity and various distortions of the fine pattern.

Thus, high energy ions of etching gases may reach bottom of a contact hole or a via hole in fine pattern structures having the high aspect ratio in a plasma etching process. A capacitively-coupled plasma (CCP) etching apparatus may be used rather than an inductively-coupled plasma (ICP) etching apparatus for the high aspect ratio patterning process.

A conventional CCP etching apparatus may include a source power unit and a bias power unit guiding the CCP to a substrate. Etch depth loadings in the CCP etching apparatus may be controlled by controlling the bias power unit to have a relatively high electric power and a relatively low duty ratio. The relatively high power of the bias power unit may result in the etching ions of the etching gases having such high energy that the etching ions reach the bottoms of the contact hole and the via hole. The relatively low duty ratio of the bias power unit may result in a break time of the bias current which is relatively short in the bias current cycle.

### SUMMARY

An exemplary embodiment of the present inventive concept provides a plasma etching apparatus forming fine pattern structures having a super aspect ratio under minimal etch depth loadings with high bias power and low duty ratio.

An exemplary embodiment of the present inventive concept provides a method of manufacturing a semiconductor device using the plasma etching apparatus.

According to an exemplary embodiment of the present inventive concept, a plasma etching apparatus includes a process chamber. A source supplier is positioned at an upper portion of the process chamber. The source supplier is configured to supply source gases for an etching process into the process chamber. A substrate holder is positioned at a lower portion of the process chamber opposite to the source supplier. The substrate holder is configured to support a substrate. A first power source is configured to apply a high frequency power to capacitively couple the source gases into a capacitively coupled plasma (CCP) in the process chamber. A second power source is configured to apply a low frequency pulse power at a low duty ratio of less than or equal to about 0.5:1. The low frequency pulse power is configured to guide the CCP toward the substrate supported by the substrate holder.

According to an exemplary embodiment of the present inventive concept, a method of manufacturing semiconductor devices includes positioning a substrate having a layered structure on a substrate holder in a process chamber. Source gases for an etching process are supplied into the process chamber. A capacitively coupled plasma (CCP) of the source gases is generated in the process chamber. The CCP is guided onto the substrate by applying a low frequency power at a low duty ratio less than or equal to about 0.5:1. The layered structure is etching in the process chamber using the CCP.

According to an exemplary embodiment of the present inventive concept, a plasma etching apparatus includes a process chamber and a substrate holder positioned in the process chamber and configured to support a substrate. A source supplier is positioned in the process chamber, wherein the source supplier is configured to supply at least one source gas. At least one first power source is provided with the plasma etching apparatus, wherein the first power source is configured to apply a power converting the at least one source gas into a capacitively coupled plasma (CCP). At least one second power source is also provided with the plasma etching apparatus, wherein the second power source is configured to apply a bias power having an electric power of from about 20 KW to about 100 KW and a duty ratio of from about 0.01:1 to about 0.5:1 to the CCP.

According to an exemplary embodiment of the present inventive concept, the low frequency power having an electric power greater than about 20 KW and a low duty ratio smaller than about 0.5:1 may be applied to the electrode as a bias power for the plasma etching process. Thus, the layer structure on the substrate may be etched into a pattern structure having contact holes or via holes of which the aspect ratio may be sufficiently high, particularly, of about 50:1 to about 100:1.

### BRIEF DESCRIPTION OF THE DRAWINGS

The above and other features of the present inventive concept will become more apparent by describing in detail exemplary embodiments thereof with reference to the accompanying drawings, in which:

FIG. 1 is a cross sectional view illustrating a plasma etching apparatus in accordance with an exemplary embodiment of the present inventive concept;

FIG. 2 is a scanning electron microscope (SEM) image showing a channel hole of a vertical NAND flash memory device when an electric power of a low frequency power increases;

FIG. 3 is a graph showing a low frequency pulse power as an exemplary embodiment of a bias power;

FIGS. 4A and 4B are graphs showing a low frequency pulse power as an exemplary embodiment of a bias power;

FIG. 5 is a cross sectional view illustrating a plasma etching apparatus in accordance with an exemplary embodiment of the present inventive concept;

FIG. 6 is a cross sectional view illustrating a plasma etching apparatus in accordance with an exemplary embodiment of the present inventive concept;

FIG. 7 is a flow chart showing a method of manufacturing a semiconductor device in accordance with an exemplary embodiment of the present inventive concept; and

FIGS. 8 and 9 are cross sectional views illustrating a method of etching a layer structure on a substrate to form a channel hole of a VNAND flash memory device in accordance with an exemplary embodiment of the present inventive concept.

### DETAILED DESCRIPTION OF THE EMBODIMENTS

Exemplary embodiments of the present inventive concept will be described below in more detail with reference to the accompanying drawings. In this regard, the exemplary embodiments may have different forms and should not be construed as being limited to the exemplary embodiments of the present inventive concept described herein. Like reference numerals may refer to like elements throughout the specification and drawings.

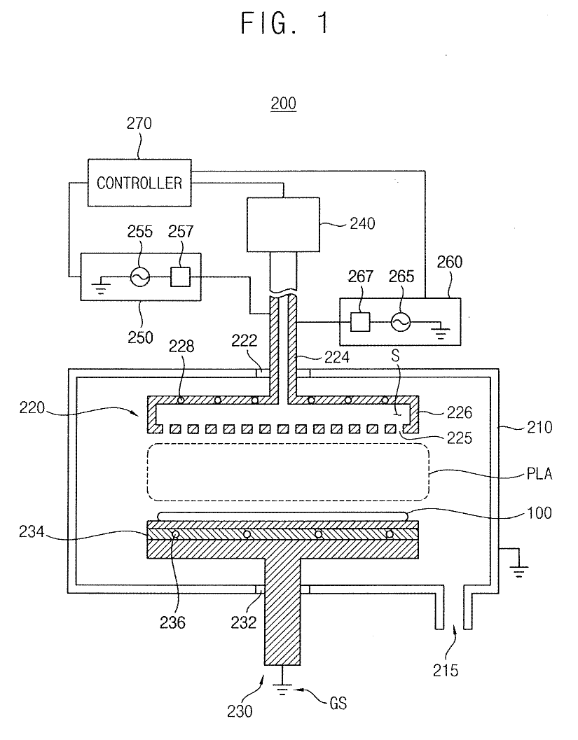

FIG. 1 is a cross sectional view illustrating a plasma etching apparatus in accordance with an exemplary embodiment of the present inventive concept.

Referring to FIG. 1, a plasma etching apparatus 200 in accordance with an exemplary embodiment of the present inventive concept may include a process chamber 210 in which an etching process using plasma is performed to a substrate 100. A source supplier 220 may be positioned at an upper portion of the process chamber 210 and may supply source gases for the etching process into the process chamber 210. A substrate holder 230 may be positioned at a lower portion of the process chamber 210 opposite to the source supplier 220. The substrate 100 may be disposed on and/or secured to the substrate holder 230. A first power source 250 may apply a high frequency power to the source gases by capacitive coupling, thus changing the source gases into a capacitively coupled plasma (CCP) in the process chamber 210. A second power source 260 may apply a relatively low frequency power at a relatively low duty ratio of less than or equal to about 0.5:1 (e.g., a low duty ratio of less than about 50%), thus guiding the CCP to the substrate 100.

As an example, the process chamber 210 may include a hollow metal body having sufficient electrical conductivity, rigidity and stiffness, so the plasma etching process may be performed at an inside of the hollow metal body.

A source tube 224 in which the source gases for the etching process may flow may penetrate through an upper portion of the process chamber 210 and a protrusion portion of the substrate holder 230 may penetrate through a bottom portion of the process chamber 210. An upper insulator 222 may be disposed between the source tube 224 and an upper plate of the process chamber 210. A lower insulator 232 may be disposed between the protrusion of the substrate holder 230 and a bottom plate of the process chamber 210. Thus, an inside of the process chamber 210 may be insulated from an outside of the process chamber 210. A chamber gate may be positioned at a sidewall of the process chamber 210 and the substrate 100 may be loaded into or unloaded from the process chamber 210 through the chamber gate. The process chamber 210 may be electrically grounded by a ground member in the plasma etching process.

An exhaust port 215 may be positioned at a bottom of the process chamber 210; however, exemplary embodiments of the present inventive concept are not limited thereto, and the exhaust port 215 may be alternatively positioned. As an example, the exhaust port 215 may be connected to a vacuum pump and byproducts of the etching process and residuals of the source gases may be exhausted from the process chamber 210 through the exhaust port 215.

The source supplier 220 may be connected to a source reservoir 240 and the source gases for the plasma etching process may be supplied into the process chamber 210 by the source supplier 220. The source reservoir 240 may include a source tank configured to hold one or more source materials for the source gases and a flow controller for controlling a mass flow of the source gases that may be transferred to the source supplier 220.

As an example, the source supplier 220 may include the source tube 224, which may transfer the source gases to the process chamber 210 from the source reservoir 240. A shower head 226 may be connected to the source tube 224 and may discharge the source gases over the substrate 100. An upper electrode 228 may be positioned in the shower head 226. The upper electrode 228 may apply a source power to the source gases in the process chamber 210, and the plasma of the source gases may be generated over the substrate 100 as etching plasma PLA.

As an example, the shower head 226 may include at least one conductive material, which may have a 3-dimensional plate shape having a gas space therein. The source gases flowing in the source tube 224 may be transferred into a gas space S of the shower head 226 and then may be discharged into the inside of the process chamber 210 through a plurality of injection holes 225. Thus, the source gases may be discharged over the substrate 100 in the process chamber 210 by the shower head 226.

As an example, the upper electrode 228 in the shower head 226 may be connected to the first power source 250 via the source tube 224. For example, the source tube 224 may include one or more conductive materials and may be provided as a wiring for the upper electrode 228. Thus, the first power source 250 may be connected to the source tube 224 and the upper electrode 228 may be connected to the first power source 250 via the source tube 224.

The source gases may be supplied into the gas space S of the shower head 226 through the source tube 224 and may be supplied into the process chamber 210 through the injection holes 225. The source gases may be changed into etching plasma PLA by the powers applied from the first and/or the second power sources 250 and/or 260, which will be discussed in more detail below. The plasma etching process according to an exemplary embodiment of the present inventive concept may be performed by using the etching plasma PLA in the process chamber 210.

The substrate holder 230 may be positioned at the bottom of the process chamber 210 opposite the source supplier 220. As an example, the substrate holder 230 may include an electrostatic chuck (ESC) or a vacuum chuck.

In an exemplary embodiment of the present inventive concept, the substrate holder 230 may include an ESC having a suceptor 234 having a plurality of electrodes. The substrate 100 may be secured to the substrate holder 230 by an electrostatic force. The ESC may include a buried electrode generating the electrostatic force and a lower electrode 236 for applying a bias power to the CCP. The CCP may be guided toward the substrate 100 by the bias power. The etching plasma PLA of the source gases may be generated by the source power or by a combination of the source power and the bias power.

Thus, the source power and the bias power may be applied to the upper electrode 228 and the lower electrode 236, respectively, and the source gases may be changed into the etching plasma PLA over the substrate 100. As an example, a plasma sheath may be provided between the substrate 100 and the shower head 226 in the process chamber 210.

The first power source 250 may be connected one of the upper electrode 228 and the lower electrode 236 and may supply a high frequency power as the source power for changing the source gases into the etching plasma PLA.

As an example, the first power source 250 may include a first power generator 255 generating the high frequency power and a first impedance matching transformer 257 matching the impedance of the high frequency power with a corresponding electrode to which the high frequency power may be transferred.

The first power generator 255 may generate the source power having such a high frequency that the source gases over the substrate 100 may be changed into capacitively coupled plasma, thus forming the etching plasma PLA in the process chamber 210. The first impedance matching transformer 257 may transform the impedance of the high frequency power according to the impedance of a corresponding electrode in such a way that the high frequency power may be substantially matched with the impedance of the corresponding electrode, thus maximizing the transfer efficiency of the high frequency power. Thus, the high frequency power may be transferred to one of the upper and the lower electrodes 228 and 236 with relatively high transfer efficiency.

For example, the high frequency power may include a radio frequency (RF) power having a frequency of from about 27 MHz to about 2.45 GHz and an electric power of from about 100 W to about 1,000 W. In an exemplary embodiment of the present inventive concept, the RF power for the high frequency power may have a frequency of from about 40 MHz to about 1.5 GHz.

The second power source 260 may be connected to one of the upper electrode 228 and the lower electrode 236. The power source 260 may supply a low frequency power as the bias power for guiding the capacitively coupled etching plasma PLA to the substrate 100. The low frequency power may be applied to the substrate holder 230. As an example, the low frequency power may be a pulsed power having a duty ratio less than or equal to about 0.5:1.

As an example, the second power source 260 may include a second power generator 265 generating the low frequency power and a second impedance matching transformer 267 matching the impedance of the low frequency power with a corresponding electrode to which the low frequency power may be transferred.

The second power generator 265 may generate the bias power having such a low frequency that the source gases over the substrate 100 may be changed into capacitively coupled plasma together with the high frequency power. Thus, the etching plasma PLA in the process chamber 210 may be formed and the PLA may be guided to the substrate 100 on the substrate holder 230. The second impedance matching transformer 267 may transform the impedance of the low frequency power according to the impedance of a corresponding electrode in such a way that the low frequency power may be substantially matched with the impedance of the corresponding electrode, thus maximizing the transfer efficiency of the low frequency power. Thus, the low frequency power may be transferred to one of the upper and the lower electrodes 228 and 236 with relatively high transfer efficiency.

As an example, the low frequency power may include a radio frequency (RF) power having a frequency of from about 1 MHz to about 10 MHz and an electric power of from about 20 KW to about 100 KW. In an exemplary embodiment of the present inventive concept, the RF power for the low frequency power may have a frequency of from about 5 MHz to about 10 MHz.

When the electric power of the low frequency power is less than about 20 KW, the etching plasma PLA might not reach bottoms of contact holes or via holes having the aspect ratio over about 50:1. Thus, etching defects such as blowing defects and clogging defects may occur in the high aspect ratio pattern structures. When the electric power of the low frequency power is more than about 100 KW, the bottoms of contact holes or via holes may be over etched by the etching plasma PLA even though the aspect ratio of the contact hole or the via hole may be over about 50:1. Thus, damage may occur in underlying structures under an etch stop layer.

Thus, the power of the low frequency power may have an electric power of from about 20 KW to about 100 KW.

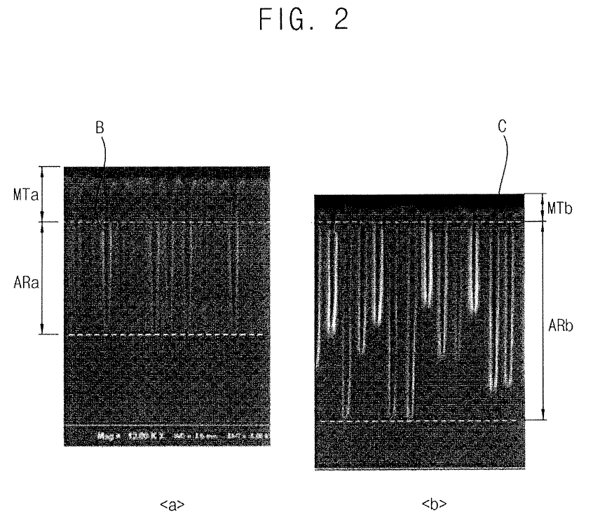

FIG. 2 is a scanning electron microscope (SEM) image showing a channel hole of a vertical NAND flash memory device when an electric power of a low frequency power increases.

Referring to FIG. 2, a left SEM image illustrated as a lowercase letter ‘<a>’ shows a channel hole of a VNAND flash memory device that may be formed by using a low frequency power of about 9.5 KW in a conventional plasma etching process. A right SEM image illustrated as a lowercase letter ‘<b>’ shows a channel hole of a VNAND flash memory device that may be formed by using the low frequency power of about 14 KW in the same conventional plasma etching. The channel holes illustrated in FIG. 2 may be formed under substantially the same etching conditions except for the electric power of the low frequency power.

Referring to FIG. 2, an effective aspect ratio of the channel hole of the VNAND flash memory device may be increased from a first aspect ratio ARa to a second aspect ratio ARb by increasing the electric power of the low frequency power in the conventional plasma etching apparatus. Thus, a bowing defect B shown in the left SEM image of FIG. 2 might not be found in the right SEM image of FIG. 2 and the channel hole of the VNAND flash memory device may be formed to have a substantially linear shape (see, e.g., the right SEM image of FIG. 2). Thus, the comparison between the left and the right SEM images in FIG. 2 indicates that the increase of the bias power or the low frequency power may sufficiently increase the effective aspect ratio without the bowing defect.

However, the increase of the bias power or the low frequency power may also decrease the thickness reduction of a mask pattern for the channel hole simultaneously with the increase of effective aspect ratio. When the electric power of the bias power is about 9.5 KW, the thickness of the mask pattern may be a first thickness MTa. The thickness of the mask pattern may be a second thickness MTb smaller than the first thickness MTa when the electric power of the bias power is about 14 KW. The smaller thickness of the mask pattern may be caused a clogging at a top portion of the channel hole. Thus, a clogging defect C may occur at an entrance of the channel hole when the electric power of the bias power is about 14 KW.

Thus, the power increase of the bias power for increasing the effective aspect ratio of the channel hole may also cause excessive etching to an upper portion of the layer structure in the plasma etching process for manufacturing the VNAND flash memory device.

When the aspect ratio of the channel hole is relatively high to such a degree of the super aspect ratio over about 50:1, the byproducts of the plasma etching process may be difficult to remove from the channel hole and the byproducts of the etching process may be re-deposited in the sidewall of the channel hole, particularly, around the entrance of the channel hole, thus forming the clogging defect C at the entrance portion of the channel hole. In an exemplary embodiment of the present inventive concept, a pulse power having a relatively low duty ratio of less than or equal to about 0.5:1 may be applied as the bias power which may reduce or prevent the clogging defect in the channel hole. Thus, the byproducts of the plasma etching process may be substantially removed from the channel hole due to the pulse power.

Thus, when the bias power is provided as a relatively low frequency pulse power having the electric power over about 20 KW and the low duty ratio smaller than about 0.5:1 in the plasma etching process according to an exemplary embodiment of the present inventive concept, the layer structure on the substrate 210 may be formed into the pattern structure having contact holes and/or via holes of which the effective aspect ratio is relatively high with relatively few clogging detects. Thus, etching defects in pattern structure having the super aspect ratio over about 50:1 may be reduced or eliminated.

In an exemplary embodiment of the present inventive concept, the low duty ratio of the pulse power may be in a range of from about 0.01:1 to about 0.5:1. When the bias power is controlled according to the pulse power having a duty ratio over about 0.5:1, the byproducts of the plasma etching process might not be sufficiently removed from a relatively deep contact hole having a super aspect ratio. Thus, byproducts may be re-deposited onto sidewalls of the contact hole around the entrance of the contact hole. When the bias power is controlled according to the pulse power having a duty ratio of less than about 0.01:1, the intensity of the bias power may be so weak that the etching plasma PLA might not reach the bottom of the relatively deep contact hole. Thus, the bias power according to an exemplary embodiment of the present inventive concept may be provided as the relatively low frequency pulse power having the duty ratio of about 0.01:1 to about 0.5:1.

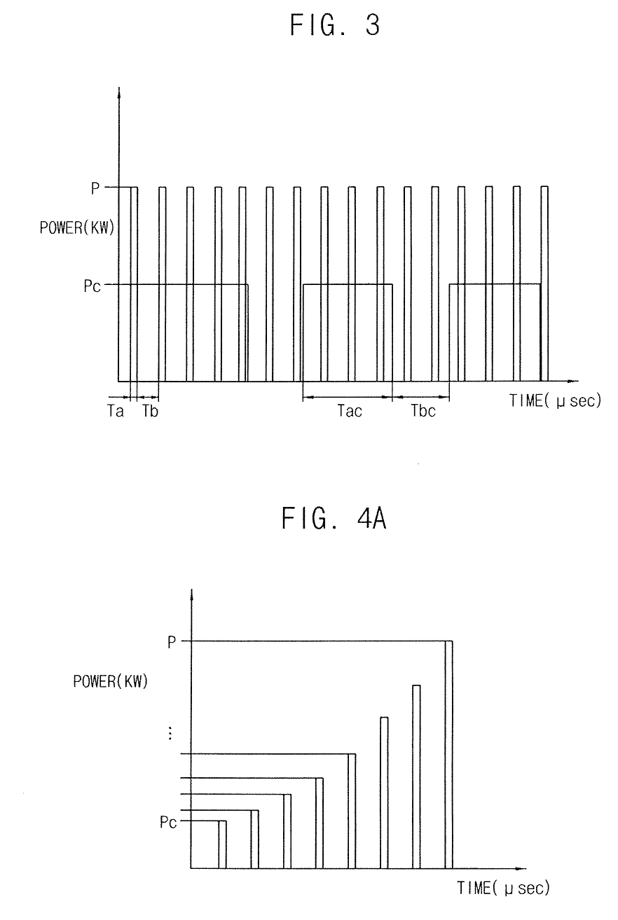

FIG. 3 is a graph showing a low frequency pulse power as an exemplary embodiment of a bias power.

Referring to FIG. 3, a conventional bias power may be provided as a low frequency continuous power or a low frequency pulse power having a conventional electric power Pc. As an example, the low frequency pulse power for the conventional bias power may have a

$$\frac{{T}_{ac}}{{T}_{bc}}$$

conventional duty ratio over about 1. In contrast, the low frequency pulse power for the bias power according to an exemplary embodiment of the present inventive concept may be controlled to have an electric power P greater than about 2 times a conventional electric power

$$\frac{{T}_{a}}{{T}_{b}}$$

Pc and the low duty ratio smaller than about 0.5:1.

Thus, according to an exemplary embodiment of the present inventive concept, in the plasma etching apparatus 200, the greater bias power may be substantially instantaneously applied for an active time Ta to the corresponding electrode and may be shut off for an inactive time Tb longer than about 2 times the active time Ta. Thus, byproducts of an etching process may be substantially removed from the inside of the contact hole and the clogging defect may be reduced or prevented at the entrance portion of the contact hole even though the aspect ratio of the contact hole may be over about 50:1.

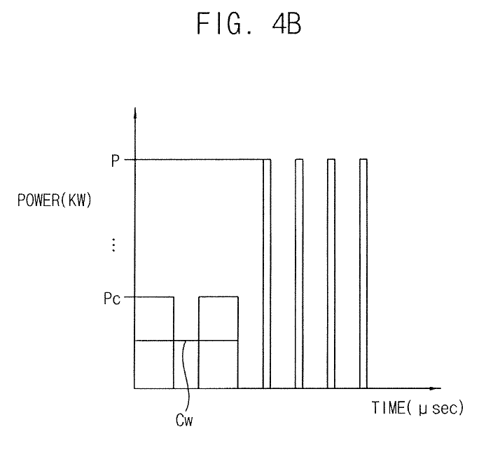

FIGS. 4A and 4B are graphs showing a low frequency pulse power as an exemplary embodiment of a bias power.

Referring to FIG. 4A, a bias power according to an exemplary embodiment of the present inventive concept may be provided as a relatively low frequency ramp power in which electric power may be ramped up step by step from a minimal value to a maximal value under a condition that a low duty ratio may be the same as that of the bias power described with reference to FIG. 3. For example, the minimal value of the electric power may correspond to the conventional electric power Pc of the conventional bias power.

Since the aspect ratio of the contact hole may be relatively small at the initial time of the etching process, the bias power having the minimal electric power Pc may be sufficient for the plasma etching process and the clogging defect may be substantially prevented as long as the duty ratio of the bias power is sufficiently small.

However, as the plasma etching process proceeds, a contact hole may become relatively deep and an aspect ratio of the contact hole may become relatively high. Thus, as the plasma etching process proceeds, the electric power of the bias power may gradually increase step by step from the minimal electric power Pc to the maximal electric power P, and thus the etching plasma PLA may have a sufficient energy for approaching the bottom of the contact hole of which the aspect ratio may increase step by step.

As an example, an overall depth of a contact hole or via hole may be divided into substantially uniform intervals and the minimal electric power of the bias power may be set as the conventional electric power Pc of the conventional plasma etching apparatus. In addition, the maximal electric power P of the bias power may be set in a range of from about 20 KW to about 100 KW. In such a case, the electric power of the bias power may be ramped up from the minimal electric power Pc to the maximal electric power P step by step corresponding to each interval in proportion to the depth of the contact hole.

Referring to FIG. 4B, a low-powered continuous power CW or a low-powered pulse power having the conventional electric power Pc may be applied as the bias power until the contact hole may have a depth corresponding to a preset level. Then, when the depth of the contact hole exceeds the preset level, the bias power may be changed into the high-powered pulse power having the electric power P. Thus, the high-powered pulse power may have a low duty ratio that may be smaller than a high duty ratio of the low-powered pulse power.

As an example, when a depth of a contact hole is smaller than a preset level, the low-powered pulse power having the high duty ratio or the low-powered continuous power may be applied as the bias power. In contrast, the high-powered pulse power having the low duty ratio may be applied as the bias power when the depth of the contact hole greater than the preset level. In an exemplary embodiment of the present inventive concept, a preset time when the depth of the contact hole may reach the preset level may be preset in the plasma etching apparatus 200 prior to the plasma etching process. The bias power may be automatically changed from the low-powered pulse power having the high duty ratio to the high-powered pulse power having the low duty ratio at the preset time.

The second power generator 265 may include a high power generator generating a high-powered low-frequency power with the low duty ratio and a low power generator generating the low-powered low-frequency power with the high duty ratio.

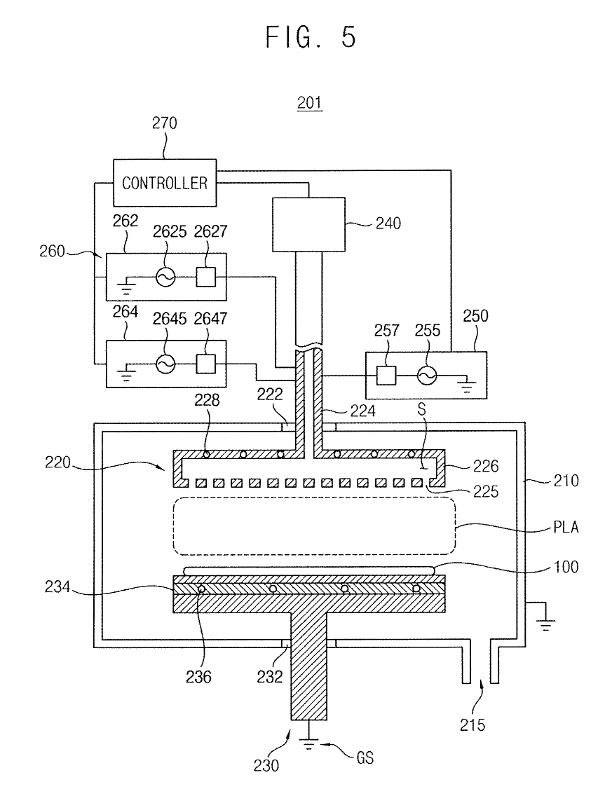

FIG. 5 is a cross sectional view illustrating a plasma etching apparatus in accordance with an exemplary embodiment of the present inventive concept.

Referring to FIG. 5, a plasma etching apparatus 201 may have substantially the same structures as the plasma etching apparatus 200 described above with reference to FIG. 1, except that the second power source 260 may include a high power source 262 and a low power source 264. Thus, duplicative descriptions may be omitted, and differences between the plasma etching apparatus 200 and the plasma etching apparatus 201 may be focused on below.

The high power source 262 may include a high power generator 2625 generating a high-powered low frequency pulse power and a high impedance matching transformer 2627 substantially matching the impedance of the high-powered low frequency pulse power with a corresponding electrode to which the high-powered low frequency pulse power may be transferred. The low power source 264 may include a low power generator 2645 generating a low-powered low frequency power and a low impedance matching transformer 2647 substantially matching the impedance of the low-powered low frequency power with a corresponding electrode to which the low-powered low frequency power may be transferred. The low-powered low frequency power may include a pulse power having a high duty ratio greater than that of the high-powered low frequency pulse power or may include a continuous power. The high-powered low frequency power may have an electrical power greater than that of the low-powered low frequency power.

As an example, the high power generator 2625 may generate the pulse power having an electric power of from about 20 KW to about 100 KW and a low duty ratio of from about 0.01:1 to about 0.5:1 similar to the second power generator 265 of the plasma etching apparatus 200 described above with reference to FIG. 1. The low power generator 2645 may generate the pulse power having an electric power of from about 5 KW to about 15 KW and a high duty ratio of from about 0.6:1 to about 1.2:1. As an example, the low power generator 2645 may generate the continuous power having no duty ratio.

Thus, the low-powered low frequency power having the high duty ratio or no duty ratio may be applied to the corresponding electrode during the first half (e.g., for a first half of an overall duration of the plasma etching process) of the plasma etching process, while the high-powered low frequency power having the low duty ratio may be applied to the corresponding electrode during the second half (e.g., for a second half of an overall duration of the plasma etching process) of the plasma etching process. Thus, the operation efficiency of the plasma etching apparatus 201 may be relatively high and may reduce or eliminate process defects in the pattern structures having the super aspect ratio.

The first and the second power sources 250 and 260 and the source reservoir 240 may be substantially systematically connected and operated by a controller 270. Thus, the supply of the source gases and the applying of the source power and the bias power may be systematically controlled in accordance with the process steps of the plasma etching process.

For example, the source gases and mass flow of the source gases, the electric power and the duty ratio of the source power and the bias power may be controlled by the controller 270 and the plasma etching process may be performed on the substrate 100 (e.g., a substrate having a single layer structure or a multi-layered structure) in the process chamber 210.

As an example, when the electric power of the bias power ramped up step by step as described with reference to FIG. 4A, or when the electric power of the bias power is increased from a low power to a high power at a preset depth of the contact hole as described with reference to FIG. 4B, the controller 270 may control the electric power of the low frequency power in substantially real time according to an etching depth of the substrate 100.

As an example, the low-powered low frequency pulse power having the high duty ratio or the low-powered low frequency continuous power may be applied by the low power generator 2645 at a beginning (e.g., at a relatively early time point in the plasma etching process) of the plasma etching process. When the controller 270 detects a preset etching depth of the contact hole or a preset etching time corresponding to the preset etching depth, the low power generator 2645 may be stopped and the high power generator 2625 may be operated by the controller 270. Thus, the high-powered low frequency pulse power having the low duty ratio may be applied to the corresponding electrode in place of the low-powered low frequency pulse power having the high duty ratio or the low-powered low frequency continuous power.

While the first and the second power sources 250 and 260 may be connected to the source suppler 220 and may be positioned over the process chamber 210 (see, e.g., FIG. 1), the position of the first and the second power sources 250 and 260 may be variously modified as long as the source power and the bias power may be applied to the upper and lower electrodes 228 and 236.

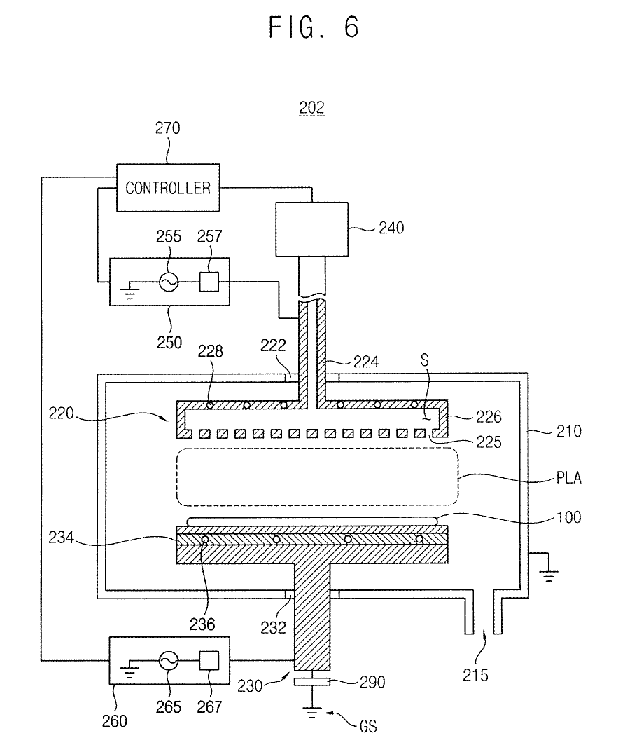

FIG. 6 is a cross sectional view illustrating a plasma etching apparatus in accordance with an exemplary embodiment of the present inventive concept.

Referring to FIG. 6, a plasma etching apparatus 202 may have substantially the same structures as the plasma etching apparatus 200 described above with reference to FIG. 1, except that the second power source 260 may be connected to the substrate holder 230 in place of the source supplier 220. Thus, duplicative descriptions may be omitted, and differences between the plasma etching apparatus 200 and the plasma etching apparatus 202 may be focused on below.

Referring to FIG. 6, the second plasma etching apparatus 202 may include the first power source 250 connected to the source supplier 220 and the source power may be applied to the to the upper electrode 228, while the second power source 260 may be connected the substrate holder 230 and the bias power may be applied to the to the lower electrode 236.

As an example, the second power source 260 may be connected to the substrate holder 230 together with a ground source GS. A high-pass filter 290 may be positioned between the substrate holder 230 and a ground source GS in such a way that only the low frequency power is applied to the substrate holder 230.

The high-pass filter 290 may allow the high frequency power to pass and may filter the low frequency power, and thus the high frequency power may be electrically grounded to earth by the high-pass filter 290 and the low frequency power may be applied to the substrate holder 230. Thus, the high frequency power may be prevented from being applied to the lower electrode 236. For example, the high-pass filter 290 may include a resistor-capacitor (RC) circuit component or an inductor-capacitor (LC) circuit component.

According to an exemplary embodiment of the present inventive concept, in the plasma etching apparatus 202, the low frequency power having an electric power greater than about 20 KW and a low duty ratio smaller than about 0.5:1 may be applied to the electrode as a bias power for the plasma etching process. Thus, the substrate 100 (e.g., a substrate including a single layer structure, or a multi-layered structure) may be etched into a pattern structure having contact holes and/or via holes of which the aspect ratio may be over about 50:1.

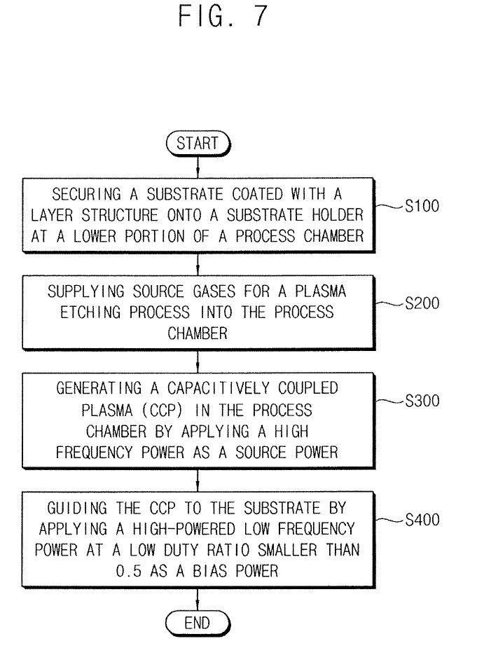

A method of etching a layer structure on a substrate using a plasma etching apparatus described above with reference to FIGS. 1 to 6 will be described in more detail below with reference to FIGS. 7 to 9.

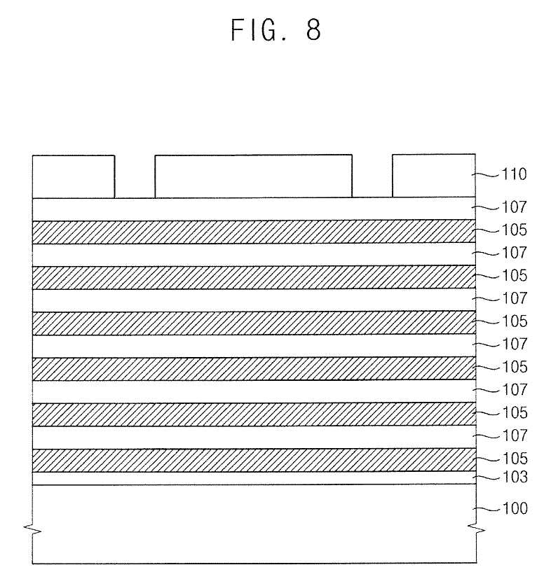

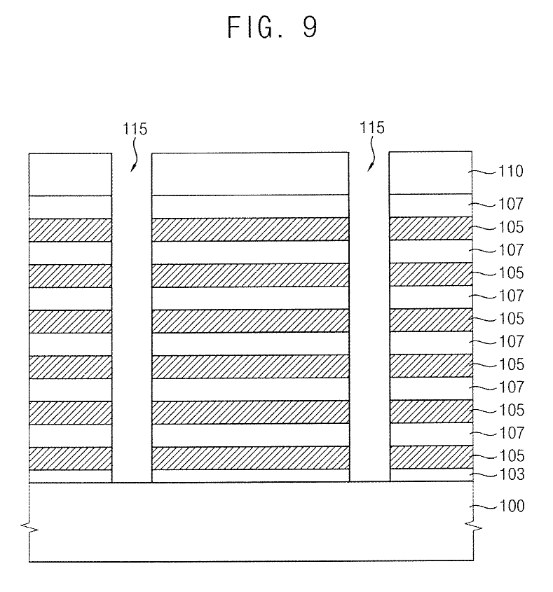

FIG. 7 is a flow chart showing a method of manufacturing a semiconductor device in accordance with an exemplary embodiment of the present inventive concept. FIGS. 8 and 9 are cross sectional views illustrating a method of etching a layer structure on a substrate to form a channel hole of a VNAND flash memory device in accordance with an exemplary embodiment of the present inventive concept.

Referring to FIGS. 7 to 9, a method of manufacturing a semiconductor device in accordance with an exemplary embodiment of the present inventive concept may include securing a substrate coated with a layered structure onto a substrate holder at a lower portion of a process chamber (step S100). For example, the substrate 100 on which a plurality of layered structures may be formed may be loaded into the process chamber 210 and may be secured onto the substrate holder 230.

For example, the substrate 100 may include a semiconductor substrate such as a silicon wafer and sacrificial layers 105 and insulation layers 107 may be alternately stacked on the substrate 100. Sacrificial layers 105 and insulation layers 107 may be provided as a vertical mold structure for manufacturing the vertical NAND flash memory device. For example, the sacrificial layer 105 may include silicon nitride and the insulation layer 107 may include silicon oxide having etching selectivity with respect to the sacrificial layer 105.

A buffer insulation layer 103 may be formed between the substrate 100 and the lowermost sacrificial layer 105 and a mask pattern 110 may be formed on the uppermost insulation layer 107.

Source gases for a plasma etching process may be supplied into a process chamber (e.g., the process chamber 210) (step S200). The source gases may be varied according to the compositions and configurations of the layered structure on the substrate 100. The controller 270 may control the source reservoir 240 to supply the source gases to the process chamber 210 together with a desired mass flow for the plasma etching process. The source gases may be supplied to the process chamber through the source tube 224 and may be scattered through the injection holes 225 of the shower head 226 in the process chamber 210.

A method of manufacturing a semiconductor device in accordance with an exemplary embodiment of the present inventive concept may include generating a capacitively coupled plasma (CCP) in the process chamber by applying a high frequency power as a source power (step S300). As an example, the source power may be applied to the upper electrode 228 of the source supplier 220 and the source gases in the process chamber 210 may be changed into the etching plasma PLA. As an example, since the high frequency power may be applied to the upper electrode 228 as the source power, a capacitively coupled plasma (CCP) of the source gases may be generated over the substrate 100. Thus, a greater electric power may be applied to the lower electrode as the bias power than the bias power for an inductively coupled plasma (ICP).

For example, the radio frequency (RF) power having a frequency of from about 40 MHz to about 1.5 GHz and an electric power of from about 100 W to about 1000 W may be applied to the upper electrode 228 by the first power source 250, thus forming the capacitively coupled plasma PLA in the process chamber 210.

A method of manufacturing a semiconductor device in accordance with an exemplary embodiment of the present inventive concept may include guiding the CCP to the substrate by applying high-powered low frequency power at a low duty ratio smaller than 0.5:1 as a bias power (step S400). As an example, the bias power may be applied to the lower electrode 236 of the substrate holder 230 and the etching plasma PLA may be guided to the substrate 100. As an example, the low frequency pulse power having a low duty ratio smaller than about 0.5:1 may be applied to the lower electrode 236. Thus, the insulation layer 107, the sacrificial layer 105 and the buffer layer 103 may be sequentially etched from the substrate 100 by the plasma etching process using the CCP, thus forming a channel hole 115 having a super aspect ratio over about 50:1.

As an example, the high-powered low frequency pulse power having the low duty ratio may be applied to the lower electrode 236 by the second power source 260. In an exemplary embodiment of the present inventive concept, the radio frequency (RF) power having a frequency of from about 1 MHz to about 10 MHz and an electric power of from about 20 KW to about 100 KW may be applied to the lower electrode 236 at a low duty ratio of from about 0.01:1 to about 0.5:1 by the second power source 260, thus guiding the CCP to the substrate 100 in the process chamber 210.

Thus, the etching plasma PLA may have sufficiently relatively high energy band such that that the plasma flux of the etching plasma PLA may reach the bottom of the channel hole 115 even when the channel hole 115 has a super aspect ratio. As an example, although the sacrificial layers 105 and the insulation layers 107 may be stacked relatively high in the vertical mold structure, the vertical mold structure may be accurately etched off from the substrate 100 in such a way that an etching face of the uppermost insulation layer 107 may be substantially coplanar with an etching face of the buffer layer 103 in the channel hole 115 even when the channel hole 115 the super aspect ratio.

Although the sacrificial layers 105 and the insulation layers 107 may be stacked on the substrate to a relatively high height according to the vertical mold structure for the VNAND flash memory device, the channel hole 115 may be accurately formed through the vertical mold structure without an occurrence of bowing defects resulting from the etching process in the plasma etching apparatuses 200, 201 or 202.

The bias power may be controlled under the low duty ratio smaller than about 0.5:1, and thus byproducts of the plasma etching process at a lower portion of the channel hole 115 may be substantially removed from the inside of the channel hole 115. Additionally, re-deposition of the byproducts to an upper portion of the channel hole 115 may be reduced or prevented. Thus, the bias power of which the duty ratio may be less than about 0.5:1 may reduce or prevent a clogging defect at the entrance portion of the channel hole 115.

Thus, the vertical mold structure may be etched without an occurrence of the bowing defects and/or the clogging defects, thus stably forming the channel hole 115 having a super aspect ratio for the VNAND flash memory device. In an exemplary embodiment of the present inventive concept, the channel hole 115 may have the super aspect ratio of about 50:1 to about 100:1. The aspect ratio of the channel hole 115 may increase according to the configurations of the bias power and the structures of the vertical mold structure.

The characteristics of the bias power may be varied according to an etching depth of the channel hole 115.

For example, a low frequency ramp power may be applied to the lower electrode 236 from a minimal electric power to a maximal electric power, as described in more detail above with reference to FIG. 4A. The minimal and the maximal electric powers may be preset at the controller 270.

The low-powered low frequency power and the low-powered high duty ratio pulse power may be sequentially applied to the lower electrode 236 as the bias power in the first half (e.g., a first half of a duration of the plasma etching process) and the second half of the plasma etching process, as described in more detail above with reference to FIG. 4B.

For example, the low-powered low frequency pulse power having an electric power of from about 5 KW to about 15 KW may be applied to the lower electrode 236 as the bias power by the second power source 260 under a high duty ratio of from about 0.6:1 to about 1.2:1 during a first half (e.g., a first half of a duration of the plasma etching process) of the plasma etching process. When an etching depth of the channel hole 115 exceeds a preset depth, the high-powered low frequency pulse power having an electric power of from about 20 KW to about 100 KW may be applied to the lower electrode 236 in place of the low-powered low frequency pulse power as the bias power under a low duty ratio of from about 0.01:1 to about 0.5:1 during the second half (e.g., a second half of a duration of the plasma etching process) of the plasma etching process.

As an example, the low-powered low frequency continuous power may be applied to the lower electrode 236 in place of the low-powered low frequency pulse power in the first half portion of the plasma etching process.

Since the aspect ratio of the channel hole 115 may be relatively small in the first half portion of the plasma etching process, an occurrence of the bowing defects and/or the clogging defects may be reduced or eliminated. Thus, the low-powered low frequency power may be used as the bias power of the plasma etching process, thus reducing the operation cost of the plasma etching apparatus.

While the mold structure or a multilayer structure for manufacturing the VNAND flash memory device may be etched into relatively a high aspect ratio pattern structure, any other layer structures including a single layer structure may also be etched into the high aspect ratio pattern structure, even when the contact hole in the single layer structure has a relatively high aspect ratio. For example, an upper electrode layer of a capacitor structure may be higher than an upper layer of the peripheral area in high integrated DRAM devices, so the bit line contact hole of the DRAM device may have a high aspect ratio. In such a case, the bit line contact hole of the DRAM device may also be formed through the upper electrode layer of a capacitor structure by using the plasma etching process according to an exemplary embodiment of the present inventive concept.

According to an exemplary embodiment of the present inventive concept, in the plasma etching apparatus and the method of manufacturing semiconductor devices, the low frequency power having an electric power greater than about 20 KW and a low duty ratio smaller than about 0.5:1 may be applied to the electrode as a bias power for the plasma etching process. Thus, the layer structure on the substrate may be etched into a pattern structure having contact holes and/or via holes of which the aspect ratio may be relatively high, for example, from about 50:1 to about 100:1.

While the present inventive concept has been particularly shown and described with reference to exemplary embodiments thereof, it will be understood by those of ordinary skill in the art that various changes in form and details may be made therein without departing from the spirit and scope of the present inventive concept

What is claimed is:

1. A plasma etching apparatus comprising:
a process chamber;
a source supplier positioned at an upper portion of the process chamber, wherein the source supplier is configured to supply source gases for an etching process into the process chamber;
a substrate holder positioned at a lower portion of the process chamber opposite to the source supplier, wherein the substrate holder is configured to support a substrate;
a first power source configured to apply a high frequency power to capacitively couple the source gases into a capacitively coupled plasma (CCP) in the process chamber; and
a second power source configured to apply a low frequency pulse power at a low duty ratio of less than or equal to about 0.5:1, wherein the low frequency pulse power is configured to guide the CCP toward the substrate supported by the substrate holder.

2. The plasma etching apparatus of claim 1, wherein the high frequency power is applied to the source supplier and the low frequency power is applied to the substrate holder.

3. The plasma etching apparatus of claim 2, wherein the second power source includes a power generator configured to generate the low frequency power as a pulse type power.

4. The plasma etching apparatus of claim 3, wherein the low frequency power includes a radio frequency (RF) power having a frequency of from about 1 MHz to about 10 MHz and an electric power of from about 20 KW to about 100 KW at a low duty ratio of from about 0.01:1 to about 0.5:1.

5. The plasma etching apparatus of claim 4, wherein the low frequency power includes a ramped power in which an electric power increases from a minimal power to a maximal power.

6. The plasma etching apparatus of claim 2, wherein the second power source includes a high power source having a high power generator configured to generate a high-powered low frequency pulse power and a low power source having a low power generator configured to generate a low-powered low frequency power, and wherein an electric power of the high-powered low frequency pulse power is greater than that of the low-powered low frequency power.

7. The plasma etching apparatus of claim 6, wherein the high-powered low frequency pulse power has an electric power of from about 20 KW to about 100 KW and a frequency of from about 1 MHz to about 10 MHz at a low duty ratio of from about 0.01:1 to about 0.5:1, and wherein the low-powered low frequency power includes a pulse power having an electric power of from about 5 KW to about 15 KW and a frequency of from about 1 MHz to about 10 MHz at a high duty ratio of from about 0.6:1 to about 1.2:1.

8. The plasma etching apparatus of claim 6, wherein the high-powered low frequency pulse power has an electric power of from about 20 KW to about 100 KW and a frequency of from about 1 MHz to about 10 MHz at a low duty ratio of from about 0.01:1 to about 0.5:1, and wherein the low-powered low frequency power includes a continuous power having an electric power of from about 5 KW to about 15 KW.

9. The plasma etching apparatus of claim 6, further comprising a controller configured to control the second power source such that the low power generator is operated and the low-powered low frequency power is generated during a first half portion of the etching process, wherein the low power generator is stopped and the high power generator is operated and the high-powered low frequency power is generated in place of the low-powered low frequency power during a second half portion of the etching process.

10. The plasma etching apparatus of claim 9, wherein an etching depth etched during the first half portion of the etching process is smaller than a preset depth of the etching process and an etching depth etched during the second half portion of the etching process is greater than the preset depth of the etching process.

11. A method of manufacturing semiconductor devices, comprising:
positioning a substrate having a layered structure on a substrate holder in a process chamber;
supplying source gases for an etching process into the process chamber;
generating a capacitively coupled plasma (CCP) of the source gases in the process chamber;
guiding the CCP onto the substrate by applying a low frequency power at a low duty ratio less than or equal to about 0.5:1; and
etching the layered structure in the process chamber using the CCP.

12. The method of claim 11, wherein the low-frequency power includes a radio frequency (RF) power having a frequency of from about 1 MHz to about 10 MHz and a power of from about 20 KW to about 100 KW at a low duty ratio of from about 0.01:1 to about 0.5:1.

13. The method of claim 11, wherein applying the low-frequency power to the CCP includes:
applying a low-powered low-frequency pulsed power to the CCP at a high duty ratio of from about 0.6:1 to about 1.2:1 in an electric power range of from about 5 KW to about 15 KW; and
applying a high-powered low-frequency pulsed power to the CCP at a low duty ratio of from about 0.01:1 to about 0.5:1 in an electric power range of from about 20 KW to about 100 KW and a wavelength range of from about 1 MHz to about 10 MHz.

14. The method of claim 11, wherein applying the low-frequency power to the CCP includes:
applying a low-powered low-frequency continuous power to the CCP in an electric power range of from about 5 KW to about 15 KW; and
applying a high-powered low-frequency pulsed power to the CCP at a low duty ratio of from about 0.01:1 to about 0.5:1 in an electric power range of from about 20 KW to about 100 KW and a wavelength range of from about 1 MHz to about 10 MHz.

15. The method of claim 11, wherein the layered structure on the substrate includes a pattern structure comprising a hole, and wherein the hole has an aspect ratio of from about 50:1 to about 100:1.

16. A plasma etching apparatus comprising:
a process chamber;
a substrate holder positioned in the process chamber and configured to support a substrate;
a source supplier positioned in the process chamber, wherein the source supplier is configured to supply at least one source gas;
at least one first power source, wherein the at least one first power source is configured to apply a power converting the at least one source gas into a capacitively coupled plasma (CCP); and
at least one second power source, wherein the at least one second power source is configured to apply a bias power having an electric power of from about 20 KW to about 100 KW and a duty ratio of from about 0.01:1 to about 0.5:1 to the CCP.

17. The plasma etching apparatus of claim 16, wherein the electric power includes a radio frequency (RF) power having a frequency of from about 1 MHz to about 10 MHz.

18. The plasma etching apparatus of claim 16, further comprising a source reservoir coupled to a controller, and a source tube connecting the source reservoir to the process chamber.

19. The plasma etching apparatus of claim 16, wherein the substrate comprises a layered structure formed on the substrate;

20. The plasma etching apparatus of claim 19, wherein the layered structure comprises a contact hole or a via structure having an aspect ratio of from about 50:1 to about 100:1.
